(19) United States
(12) Patent Application Publication
(10) Pub. No.: US 2011/0101956 A1
(43) Pub. Date: May 5, 2011

(54) Electricity Usage Monitor System

(76) Inventor: David Wayne Thorn, Melbourne Beach, FL (US)

(21) Appl. No.: 12/939,997

(22) Filed: Nov. 4, 2010

Related U.S. Application Data
(60) Provisional application No. 61/257,884, filed on Nov. 4, 2009.

(51) Int. Cl. G01R 19/00

(52) U.S. Cl. 324/76.11

(57) ABSTRACT

A system for monitoring electricity usage comprising a plurality of sender units having sender identification tags wherein the plurality of sender units are capable of being connected to AC power distribution wiring that carries AC waveforms, and wherein the plurality of sender units are capable of being in electrical communication with an appliance having a current draw; and a central detector capable of being connected to the AC power distribution wiring wherein the plurality of sender units are capable of being in electrical communication with the central detector through the AC power distribution wiring, and wherein the plurality of sender units are capable of transmitting a transient pulse on the AC power distribution wiring wherein the transient pulse is embedded at a location on the AC waveform wherein the location is relative to the sender identification tag and wherein the location is further relative to the current draw of the appliance.

### CROSS REFERENCE TO RELATED APPLICATIONS

This application claims the benefit of provisional patent application Ser. No. 61/257,884, filed with the USPTO on Nov. 4, 2009, which is herein incorporated by reference in its entirety.

### STATEMENT REGARDING FEDERALLY SPONSORED RESEARCH OR DEVELOPMENT

Not applicable.

### INCORPORATION-BY-REFERENCE OF MATERIAL SUBMITTED ON A COMPACT DISK

Not applicable.

### BACKGROUND OF THE INVENTION

1. Field of the Invention

The present invention generally relates to electricity usage measurement, more specifically, the present invention relates to measuring electrical usage by appliance or circuit and reporting that electricity usage by means of the electrical infrastructure.

2. Background Art

Existing methods of monitoring electricity usage are large plug-in modules and current sensor clamps. The problems with the existing methods include that (1) they are expensive per appliance and per socket devices, (2) they require consumer set up and maintenance including databases and location changes, (3) there are no easy provisions for light switches and HVAC, water heater, and similar appliance measurements require current clamps, (4) complex data transmission protocols are used within the building, reducing reliability and increasing size and cost, and (5) do not allow an easy mass deployment solution.

### BRIEF SUMMARY OF THE INVENTION

In accordance with one embodiment, the system comprises a plurality of sender units and a receiver unit. The sender units are connected to a central detector through the AC power distribution wiring. Each sender unit may have an associated sender identification tag and be connected to an appliance which draws power from the AC power distribution wiring. The sender unit may detect how much power is drawn by the appliance to which it is connected. The sender unit may transmit a transient pulse onto the AC waveform carried on the AC power distribution wiring. The sender unit can place the transient pulse on the AC waveform relative to the zero crossing of the AC waveform in such a way that the location of the transient pulse provides information to the central detector. The AC waveform may be broken up into segments so that each segment is associated with a particular sender identification tag. When a transient pulse appears on the segment of the waveform associated with sender identification tag X, the central detector can determine that the sender unit with sender identification tag X transmitted the transient pulse. Furthermore, the location of the transient pulse within the segment allotted to the sender unit sending the pulse may communicate information to the receiver unit, such as current drawn by the appliance connected to the sender unit.

### BRIEF DESCRIPTION OF THE DRAWINGS

A better understanding of the present invention will be realized from the detailed description that follows, taken in conjunction with the accompanying drawings, in which:

FIG. 1 depicts a perspective view of an Electricity Usage Monitor System.

FIG. 2 depicts an AC waveform.

FIG. 3 depicts an enlarged section of the AC waveform.

FIG. 4 depicts one embodiment of a block diagram of the sender unit.

FIG. 5 depicts transient pulses embedded on the carrier AC waveform.

FIG. 6 depicts one embodiment of the sender unit.

FIG. 7 depicts appliance waveforms.

FIG. 8 depicts a block diagram of the central detector.

FIG. 9 depicts the AC distribution interface and filters.

FIG. 10 depicts a data acquisition interface.

FIG. 11 depicts the sender unit AC interface.

FIG. 12 depicts an alternate embodiment of the AC interface.

FIG. 13 depicts yet another alternate embodiment of the AC interface.

FIG. 14 depicts yet another alternate embodiment of the AC interface.

FIG. 15 depicts an embodiment of the sender unit.

FIG. 16 depicts an embodiment of the sender unit.

FIG. 17 depicts an embodiment of the sender unit.

FIG. 18 depicts an embodiment of the sender unit.

FIG. 19 depicts an inline embodiment of the sender unit packaging.

FIG. 20 depicts a snap on embodiment of the sender unit packaging.

FIG. 21 depicts an embodiment of the sender unit.

FIG. 22 depicts an embodiment of the sender unit.

FIG. 23 depicts an embodiment of the sender unit.

FIG. 24 depicts an block diagram of an alternative embodiment of the sender unit.

FIG. 25 depicts an embodiment of the sender unit.

FIG. 26 depicts an embodiment of the AC line pulse injection circuitry.

FIG. 27 depicts an embodiment to generate the control pulse for the oscillator.

FIG. 28 depicts the output waveform of the AC line pulse injection circuitry.

### DETAILED DESCRIPTION OF THE INVENTION

Although the following detailed description contains many specifics for the purposes of illustration, anyone of ordinary skill in the art will appreciate that many variations and alterations to the following details are within the scope of the invention. Accordingly, the following preferred embodiments of the invention are set forth without any loss of generality to, and without imposing limitations upon, the claimed invention.

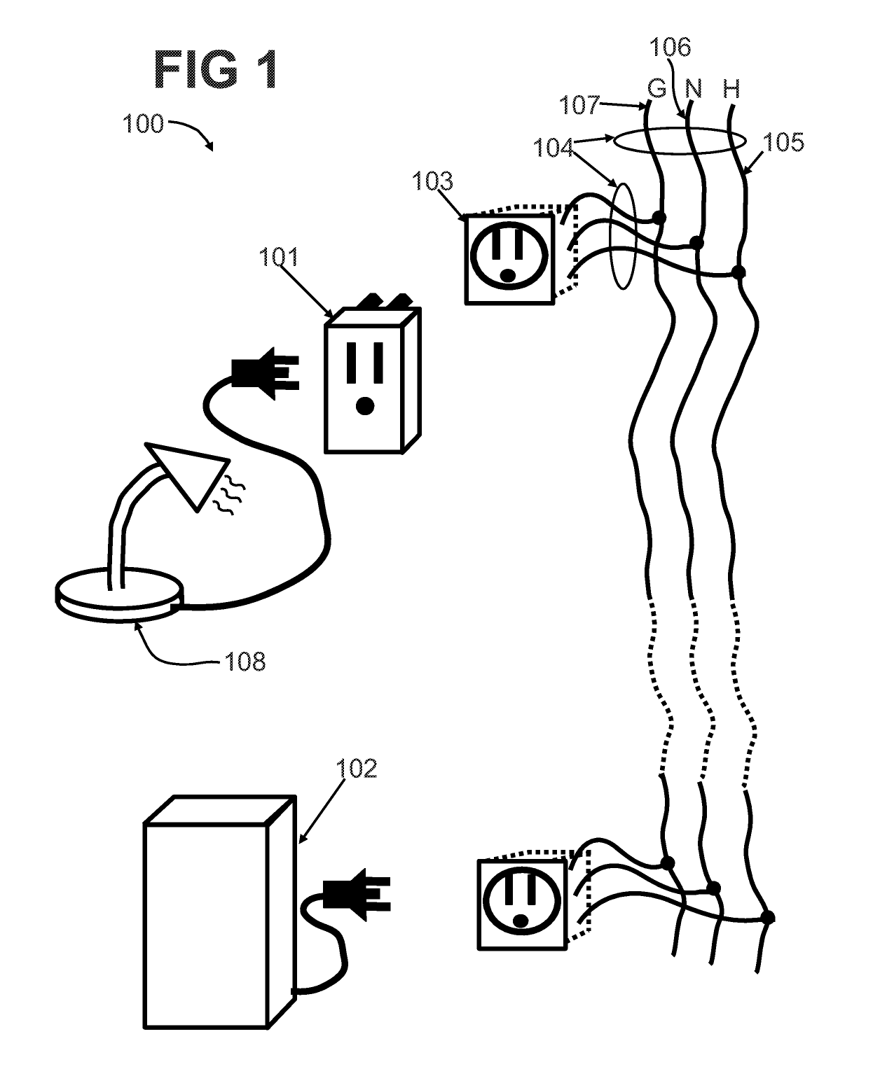

FIG. 1 depicts one embodiment of the electricity usage monitor system 100. The electricity usage monitor system 100 may comprise a plurality of sender units 101 and a central detector 102. The plurality of sender units 101 may be in electrical communication with the central detector 102 over AC power distribution wiring 104. This may be accomplished by connecting both the plurality of sender units 101 and the central detector 102 to the AC power distribution wiring 104. The AC power distribution wiring 104 may carry AC waveforms. Each sender unit 101 may be connected to an appliance 108 that draws current from the AC power distribution wiring 104. In systems comprising more than one sender unit 101, each sender unit 101 may have a sender identification tag. Each sender unit 101 may transmit a transient pulse onto the AC power distribution wiring 104. The waveform may be divided up into a number of sections, each identified by its position relative to the zero crossing of the AC waveform. Each sender unit 101 may transmit its transient pulse onto the AC waveform in the section related to the sender identification tag of the sender unit 101. The sender unit 101 may further position its transient pulse on the AC waveform relative to the current drawn by the appliance 108 connected to the sender unit 101.

In a preferred embodiment, there may be multiple sender units 101 installed within a single building or electrical system. Each sender unit 101 may be connected to a different appliance. The sender unit 101 may also be connected to the AC power distribution wiring 104. The sender unit 101 may be installed external to an AC outlet 103 which is connected to AC power distribution wiring and simply plug in to the AC outlet or the sender unit 101 may be installed within the wall circuitry for the AC outlet 103. Alternatively, the sender unit 101 may be installed within an electrical socket or within breaker panel circuitry.

The sender unit 101 may allow AC current to flow from the AC power distribution wiring 104 to the appliance 108. The sender unit 101 may detect when this current is flowing and, upon this detection and for as long as this current is flowing, the sender unit 101 may inject repeated transient pulses onto the AC waveform carried by the AC power distribution wiring 104.

Each sender unit 101 may have a sender identification tag associated with the sender unit 101. This tag may allow the central detector to determine which sender unit 101 transmitted the transient pulse. The sender identification tag may be assigned to each sender unit 101 by placing capacitive, inductive, or copper circuitry in a tape and applying this tape to conductive points on the sender unit 101. This tape may cause the sender unit 101 to locate transient pulses corresponding to the attributes of the tape. In place of tape, a physical circuit card or plug-in type device may also be used.

An AC outlet 103 may be a standard three-prong or two-prong AC power outlet as commonly found in many American residences. The AC outlet 103 may also be any electrical outlet which may provide AC power, such as, a NEMA 1, NEMA 5, NEMA 2, NEMA 6, NEMA 10, NEMA 14, NEMA TT-30 receptacle, or the like. The AC outlet 103 may comprise electrical switches, appliance wires, building AC wiring, or the like. The sender unit may be capable of connecting to any of these, or like, receptacles.

The sender unit 101 receptacle for the appliance 108 plug and the AC outlet 103 receptacle for the sender unit 101 plug may be standard electrical receptacles for 15 amp 110Vac 60 Hz, 20 amp 110Vac 60 Hz, 30 amp 240 Vac 60 Hz, or other standards allowed by the appropriate electric code of the area.

An appliance 108 may plug into the sender unit 101, or otherwise be electrically connected to the sender unit 101. The appliance 108 may have a NEMA 1, NEMA 5, NEMA 2, NEMA 6, NEMA 10, NEMA 14, NEMA TT-30 plug, or the like. The sender unit 101 may have the corresponding receptacle to allow connection of the appliance 108 to the sender unit 101. The appliance 108 may be a household appliance such as, a lamp, toaster, microwave, refrigerator, or the like. Alternatively, the appliance 108 may be industrial equipment, a motor, AC compressor unit, AC air handler unit, water heater, copy machine, bottle filling machine, or the like.

The central detector 102 may plug into an AC outlet 103. Alternatively, the central detector 102 may be electrically connected to the AC power distribution wiring 104 by other means, such as, direct wiring, integration into an AC outlet 103, or the like.

The central detector 102 may detect transient pulses that are transmitted by the sender unit 101. The transient pulse may contain information regarding which sender unit 101 transmitted the pulse, how much current is being used by the appliance 108 connected to the transmitting sender unit 108, how much power is being consumed by the appliance 108 connected to the transmitting sender unit 108, and the like. The central detector 102 may store that information for generation of reports, send that information to other systems, or the like.

The AC power distribution wiring 104 may comprise three wires designated as H wire 105, for hot wire, N wire 106, for neutral wire, and G wire 107, for ground wire. In some embodiments, the G wire 107 may be absent and is not required for the performance of the electricity usage monitor system. The AC power distribution wiring 104 may be wiring which is commonly found in residences or commercial buildings to carry AC power throughout the building. The AC power distribution wiring 104 may carry electricity as AC waveforms.

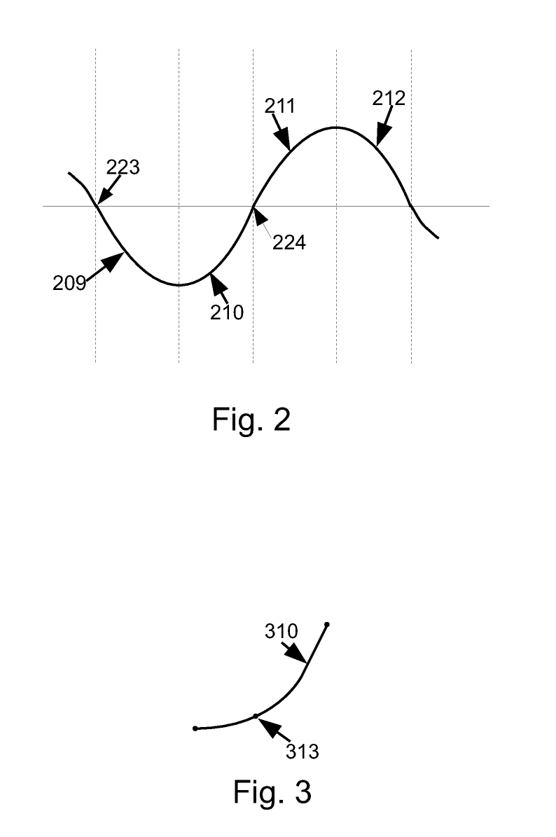

FIG. 2 depicts an example of one cycle of an AC waveform with zero crossing 1 223 and zero crossing 2 224. This AC waveform may be divided into several sections. As shown in FIG. 2, the AC waveform is divided into four sections. Section 1 209, section 2 210, section 3 211, and section 4 212. Such a division of the AC waveform into four sections may be appropriate in electricity usage monitor systems in which there are four or fewer sender units. For example, in an electricity usage monitor system having three sender units, each sender unit would have a sender identification tag. The sender units may have sender identification tags A, B, and C. Sender identification tag A may be associated with section 1 209, sender identification tag B may be associated with section 2 210, and sender identification tag C may be associated with section 3 211. When the central detector detects a transient pulse in section 2 210, it will know that the transient pulse was sent by the sender unit with sender identification tag B.

The transient pulse may appear on every cycle of the AC waveform, however the reliability or efficacy of the system may not be affected if not all transient pulses are detected. Multiple pulse detection may improve the reliability of the system.

FIG. 3 depicts an enlargement of section 2 310 of an AC waveform. The transient pulse's location on section 2 310 may communicate information to the central detector 102 such as, for example, current drawn by the appliance, power used by the appliance, or the like. As an example, if the transient pulse appears on section 2 310 at location A 313 the central detector could determine the current drawn by the appliance connected to the sender unit associated with section 2 based on the value of current draw associated with location A 313.

The central detector 102 may use the information regarding current drawn by the appliance 108 that is contained in the transient pulse and the programmed building voltage distributions to calculate associated power. That is, the central detector 102 may store values indicating the voltage levels at a plurality of AC outlets 103 or measure voltage levels directly. When the central detector 102 receives the current draw information embedded in the transient pulse, this may be combined with the known voltage level and power drawn by the appliance 108 may be calculated. The central detector 102 may store the current information derived from transient pulses transmitted from all installed sender units 101 and use that information to generate current or power usage reports and to transmit current or power usage information to other systems.

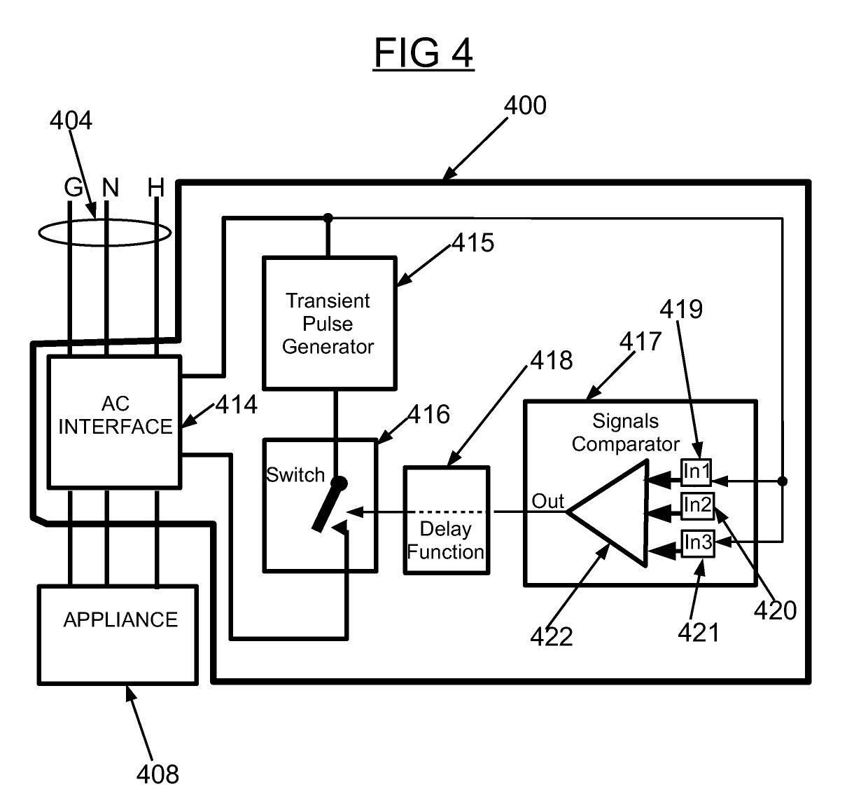

FIG. 4 depicts a block diagram of the sender unit 401. Within the Sender Unit 401 there is an AC Interface 414 which provides the circuitry to interface the AC power distribution wiring 404 to the appliance 408 and to the other internal circuit blocks of the Sender Unit 401, which may include the Transient Pulse Generator 415, Switch Circuitry 416, Signals Comparator 417 and a Delay Function 418. The delay function 418 is not a necessary component of the sender unit and may be omitted entirely in some embodiments. This diagram does not include the industry protection and bias circuitry that may also be included and is well known in the art.

The signals comparator 417 block may turn on and turn off the Switch circuitry 416 depending on the conditions of the inputs to the signals comparator 417 and depending on the active or nonactive state of the Delay Function 418.

When the Switch circuitry 416 turns on and completes a circuit through the Transient Pulse Generator 415 and the AC Interface 414, the Transient Pulse Generator 415 generates a transient pulse the basic characteristics of which are embedded onto the AC power distribution Wiring 404 through the AC Interface 414. The transient pulse's basic characteristics may be such that the Central Detector can identify that this transient pulse is from a Sender Unit belonging to this Electric Usage Monitor System. The transient pulse that appears in various places on the building AC power distribution wiring will be different from the transient pulse that appears at the Transient Pulse Generator 415 circuitry but will still retain unique characteristics for the particular Sender Unit 401 and the current being drawn by the appliance 408.

The Delay Function 418 may cause a forced delay from one closing of the Switch circuitry 416 to the next closing of the Switch circuitry 416. This regulates the number of Transient Pulses per second being transmitted on the building AC power distribution wiring 404 to make it easier for the Central Detector to detect all pulses from the multiple Sender Units installed in the building.

The Signals Comparator 417 produces an output to turn on the Switch circuitry 416 at a unique location on the AC power distribution waveform 404. The unique location is derived from the three functions: ln 1 Function 419, ln 2 Function 420, and ln 3 Function 421. The output of the Ln 1 function 419 provides an input to the Comparator Function 422 relative to the current being delivered to the appliance 408. The output of the ln 2 Function 420 provides an input to the Comparator Function 422 relative to the sender identification tag associated with the particular Sender Unit 401. The output of ln 3 Function 421 provides an input to the Comparator Function 422 relative to the voltage level of the AC power distribution wiring 404 waveform. The comparator function 422 uses these inputs to output a signal, which is the output of the signals comparator 417. This output controls the switch circuitry 416 and causes the switch circuitry 416 to be turned on at a unique point on the AC power distribution wiring 404 waveform relative to the zero point crossing of the AC power distribution wiring 404 waveform.

When the delay function 418 receives a turn on input from the signals comparator 417, it will pass the signal through to the switch circuitry 416 and start a time out function if the current time out function has expired. If the current time out function has not expired, the Delay Function 418 will not pass the signal through to the switch circuitry 416. This Delay Function 418 provides a way to prevent generating a Transient Pulse on every cycle of the building AC distribution waveform and instead generates the Transient Pulse at a lower repetition rate. This repetition rate reduction can reduce the processing work required of the Central Detector but still be often enough to determine the current flow into the appliance 408 at a time resolution adequate for use in determining the significant effect of the appliance 408 on the total building power usage.

A Transient Pulse may also be generated when the switch circuitry 416 transitions from on to off. The transient pulse generated in this manner may have different characteristics than the transient pulse generated when the switch circuitry 416 is on, but may also be used by the Central Detector to receive information from a Sender Unit in the Electricity Usage Monitoring System.

There may be a plurality of electricity usage monitor systems connected to a single AC power distribution wiring. Therefore, a central detector may receive transient pulses sent from multiple electricity usage monitor systems. The central detector may analyze different characteristic of the transient pulse, such as, for example, the frequency, the decay characteristic, the duration, the relative amplitude of frequencies, or the like, to determine if the transient pulse was sent by a sender unit on the same electricity usage monitor system as the central detector.

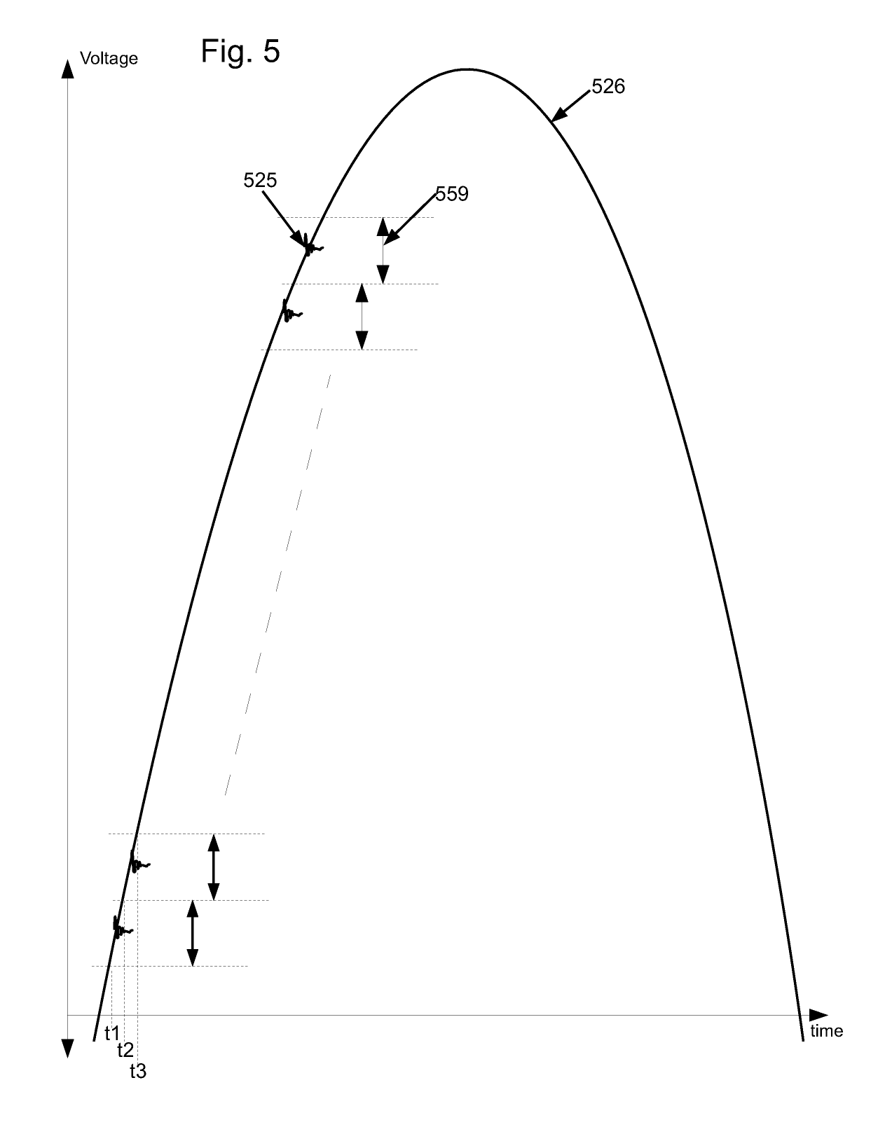

Referring to FIG. 5, an example of transient pulses 525 embedded in the first cycle of the carrier AC power distribution wiring waveform 526 may be seen. FIG. 5 depicts the transient pulses 525 on the first quarter cycle of the AC power distribution wiring waveform 526, but the Electricity Usage Monitor System may allow for transient pulses 525 to be impressed on the other three quarter cycles as well. The location of the transient pulse 525 within a given sender unit range 559 may indicate that the sender unit transmitting the transient pulse 525 is the sender unit with the sender identification tag associated with the sender unit range 559 in which the transient pulse appears. As shown in FIG. 5, there may be more than one transient pulse 525 embedded on each waveform. In the preferred embodiment, the transient pulse 525 may be used communicate information about power or current consumption. However, in alternate embodiments, the transient pulse 525 may be embedded onto a power signal at varying locations on the signal to communicate a variety of information. The central detector may detect the transient pulse 525 on the power signal and use the location of the transient pulse 525 to determine information other than current or power draw. Circuitry may be designed by one skilled in the art to use this inventive transient pulse 525 protocol to communicate information such as water usage, noise levels, traffic light status, pulse, blood pressure measurements, temperature date, solar panel operational data statistics, or the like based on the location of the transient pulse relative to the zero crossing point of the AC waveform onto which the transient pulse is embedded.

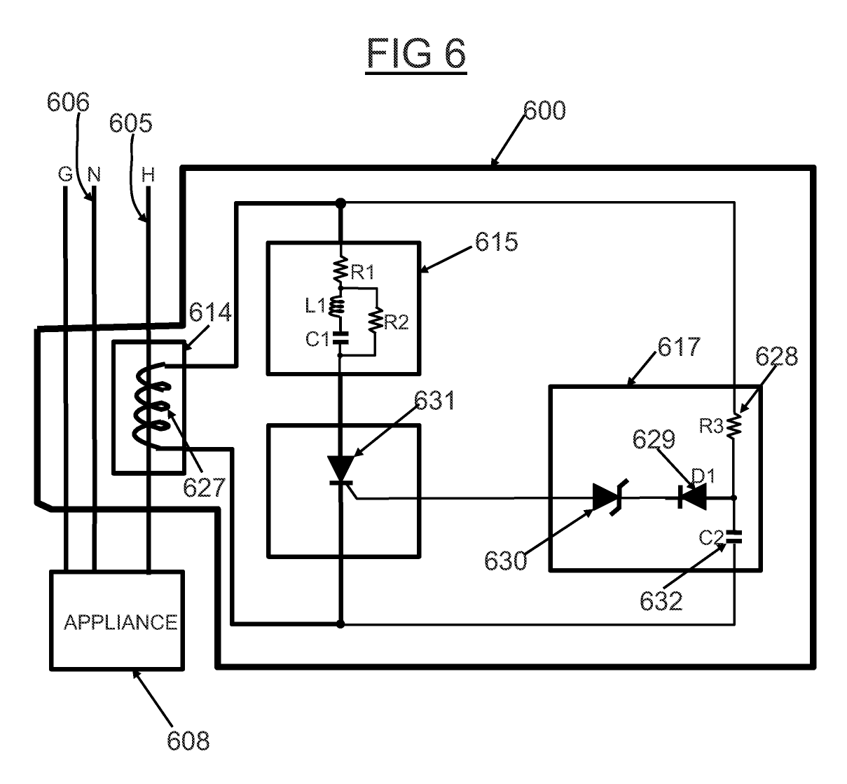

Referring to FIG. 6, a more detailed block diagram of one possible embodiment of the sender unit 601 may be seen. The embodiment shown in FIG. 6 may generate the transient pulses as shown in FIG. 5. Alternative embodiments or alternative component values may be used for generating the pulse on second quarter cycle, third quarter cycle, and fourth quarter cycle of the AC power distribution wiring waveform.

The Delay Function is not depicted in the embodiment shown in FIG. 6. However, a delay function may be implemented in this embodiment using typical resistor-capacitor, resistor-capacitor-transistor, or passive and digital components combined in ways that are well known in the art.

The AC Interface 614 is shown as a coil 627 around the H wire 605. This coil 627 may be a clamp on coil, a wired in transformer, direct discrete components connected in series and parallel with the H wire 605 and or the N wire 606.

When current flows to the appliance 608, a current is caused to flow in the coil 627, through resistor R3 628, diode D1 629, zener diode 630, into the gate of SCR 631, out of the cathode of SCR 631, back to the other end of the coil 627. In addition, current will flow through capacitor C2 632. This causes a phase shift which allows the SCR 631 to fire at a different point in time as referenced to the zero crossing point of the AC power distribution wiring waveform than the SCR 631 would fire without capacitor C2 632. Varying the value of capacitor C2 632 allows the SCR to be turned on at different locations on the AC power distribution wiring waveform. Different sender units 601 within the same electricity usage monitor system may have different capacitor C2 632 values which will allow each sender unit 601 to place a transient pulse at a unique location on the AC power distribution wiring waveform. Note that this is AC current and in the embodiment shown in FIG. 6 only the positive cycle of the current waveform would cause this current just described to flow. Similar circuitry would be used for the negative cycle.

When this current including the phase shift caused by capacitor C2 632 becomes high enough to cause the voltage at the gate of SCR 631 to fire, SCR 631 will turn on and conduct current in the loop consisting of the coil 627, Transient Pulse Generator 615, SCR 631 anode-cathode, and back to coil 627. When the current first starts flowing, a transient pulse will be generated which lasts a very short period relative to the AC power distribution wiring waveform period. The specific characteristics of this transient pulse are controlled by the transient pulse generator 615, which may comprise an RLC circuit, and also by SCR 631 switching characteristics. Current continues flowing in this loop until it decreases to near the zero crossing point which causes SCR 631 to turn off. A different transient pulse may be generated at the turn-off time and this turn off time transient pulse may be ignored by the Central Detector or it may be used in conjunction with the turn on time transient pulse for validating that the transient pulses were generated by a Sender Unit 601.

Further, still referring to FIG. 4, each component is shown in the functionality box for which the component primarily is used for, however, most components help provide functionality in several functionality boxes.

In more detail, referencing FIG. 4, the ln 1 function 419 that provides an input to the comparator function 422 relative to the current being delivered to the appliance 408 may comprise, referring to FIG. 6, Resistor R3 628, SCR 631, and capacitor C2 632. The ln 2 Function 420 that provides an input to the comparator function 422 relative to which unique Sender Unit 401 is generating the transient pulse may comprise Resistor R3 628, capacitor C2 632, SCR 631, and Zener diode 630. Zener diode 630 may be an optional component and may be added as needed to sender units 601 to allow the transient pulse to occur at higher voltages. The ln 3 Function 421 that provides an input to the comparator function 422 relative to the AC power distribution wiring waveform voltage may comprise Resistor R3 628, SCR 631, capacitor C2 632, zener diode 630 and diode D1 629. The comparator function 422 that determines when the switch circuitry 416 is turned on and off may comprise SCR 631, the components of the signals comparator 617, capacitor C2 632, zener diode 630, and diode D1 629.

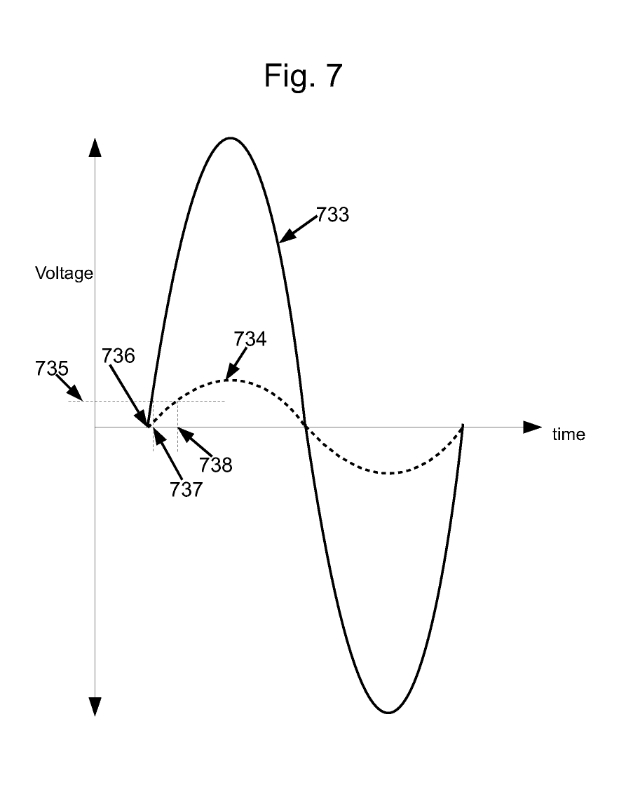

FIG. 7 shows an appliance high voltage waveform 733, an appliance lower voltage waveform 734, an SCR trigger voltage point 735, voltage waveform zero crossing 736, low voltage trigger time 738, and high voltage trigger time 737. The waveforms shown in FIG. 7 are not to scale.

The high voltage waveform 733 and the lower voltage waveform 734 are two example voltage waveforms that may occur at coil 627 of FIG. 6. High voltage waveform 733 may occur when high current is flowing to the appliance 608 and lower voltage waveform 734 may occur when relatively lower current is flowing to the appliance 608. Also shown is an SCR trigger voltage point 735 that is needed across coil 627 to cause SCR 631 to turn on for a particular Sender Unit 601. This SCR trigger voltage point 735 may be varied from one Sender Unit to another by varying the values of Resistor R3 628 and Zener diode 630. In addition, the position of triggering SCR 631 in relation to the voltage waveform zero crossing 736 may be varied by capacitor C2 632 which may cause a phase shift of the waveform into the gate of SCR 631. This time variation is not shown in FIG. 7.

When higher current is flowing as depicted by high voltage waveform 733, SCR 631 will turn on at high voltage trigger time 737 and thus a transient pulse will occur at high voltage trigger time 737. When lower current is flowing as depicted by lower voltage waveform 734, SCR will turn on at low voltage trigger time 738. Both of these times are relative to the voltage waveform zero crossing 736 of either waveform. Both these transient pulses will cause a corresponding Transient Pulse to be embedded on the AC power distribution wiring at corresponding time. Thus, when lower current is flowing to the appliance the Transient Pulse will be in a different place and earlier in time relative to the voltage waveform zero crossing 736 on the AC power distribution wiring waveform than when higher current is flowing to the appliance.

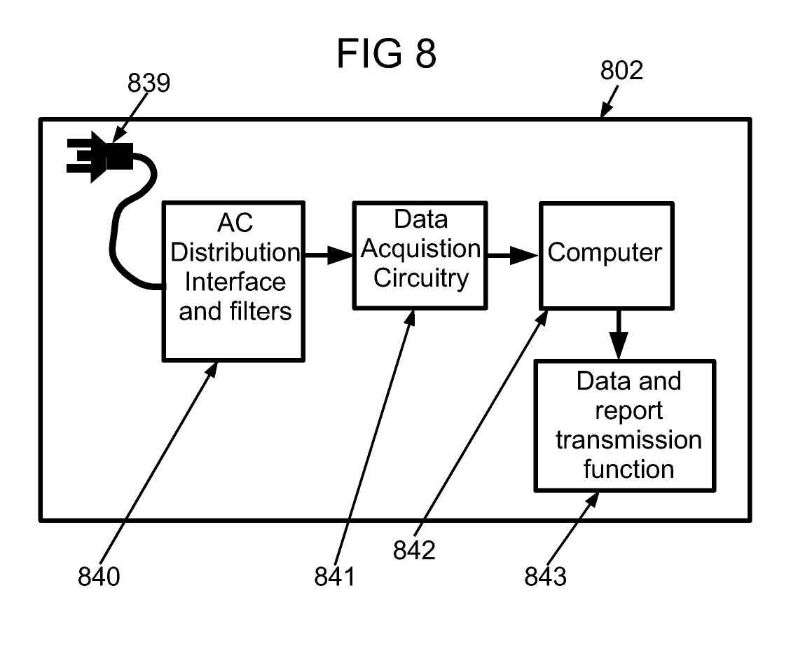

FIG. 8 shows a preferred embodiment of the Central Detector 802 comprising an AC outlet plug 839, AC Distribution Interface and filters 840, data acquisition circuitry 841, a computer 842, and a data and report transmission function 843.

The AC outlet plug 839 may be standard USA electrical standards for 15 amp 110Vac 60 Hz, or 20 amp 110Vac 60 Hz or 30 amp 240Vac 2 phase 60 Hz, or other standards allowed by the appropriate electric code of the area. The AC outlet plug 839 provides connection of the Central Detector 802 to the H wire and the N wire of the AC power distribution wiring. It may also provide connection to the G wire. In one embodiment, the AC outlet plug 839 may comprise direct, hard wiring to the AC power distribution wiring rather than a removable plug.

The AC distribution interface and filters 840 may provide conversion and filters needed to provide the AC waveform signal from the AC power distribution wiring to the Data acquisition circuitry 841. The data acquisition circuitry 841 in a preferred embodiment may be a commercially available data acquisition module, analog to digital converter module, or the like with a standard interface to a computer 842. This interface may be USB, Ethernet or like computer interfaces. Another example of commercially available interface includes those sold as oscilloscope modules with software to allow full oscilloscope functionality via a PC. The data acquisition circuitry 841 may have a minimum of 10 bit resolution but a preferred embodiment may have 12 bit resolution or greater on each of the two input ports. In a preferred embodiment, the data acquisition circuitry 841 may have a sampling less than 1 million samples per second with a preferred rate of 1 million samples per second or greater.

In a preferred embodiment, the computer 842 may be a commercially available machine with enough processor power, RAM, hard drive and other such attributes to run commercially available software applications that come with or are compatible with the data acquisition circuitry 841 along with special software programs for data, time and frequency analysis including programs performing Fast Fourier Transforms and other math and statistical analysis required. The computer 842 may be an embedded type computer where there is no monitor or keyboard but instead a single box or a circuit board(s) that go into a custom box. The computer 842 processing must also be fast enough to process a large number of samples and detect multiple Transient Pulse signals from the same Sender Unit that occur within one second of each other or even faster. Transient Pulses from the same Sender Unit may occur faster than once per second but the resolution of the appliance current usage over time will be more than adequately useful using the once per second requirement. Such computers 842 are well known to those skilled in the art.

The computer 842 may perform analysis on the signals coming from the data acquisition circuitry 841 in order to identify the multiple Transient Pulses that belong to the Electricity Usage Monitor System associated with the central detector 802 of which the computer is a component, identify which Sender Unit in the electricity usage monitor system each Transient Pulse came from and identify from each Transient Pulse the amount of current or power that was being drawn by the appliance. The computer 842 may store this information and later generate various reports about the current and calculated power used by each appliance over time, compared power or current used by one appliance to overall current or power consumption, compared appliance power or current consumption to other normal electric usage parameters, or the like. The computer may then transmit these reports to other equipment, to a display unit, display it directly, or the like.

In setting up and designing any software for the computer 842 a machine learning software application could be used that that learns characteristics of the transient Pulse. The results of this learning process may be used to help program the actual production units but the machine learning software may not be required in the actual production units.

In addition to commercially available software applications, the computer 842 may also have custom designed applications to assist in signals analysis and reports generation. This may include custom data handling communication with existing products and higher level protocols such as required for existing electricity usage reporting and display programs.

The data and report transmission function 843 may be comprised of commercially available hardware and software and it may receive the data formatted by the computer and transmit it to other equipment, display the data, print the data, or the like. The data and report transmission function 843 may be embedded in the commercially acquired computer or may be separate commercially acquired units interfacing to the computer through USB or the like and using wired or wireless communication operations such as WiFi, Zigbee, Ethernet, USB, Bluetooth and cellular to communicate with other equipment.

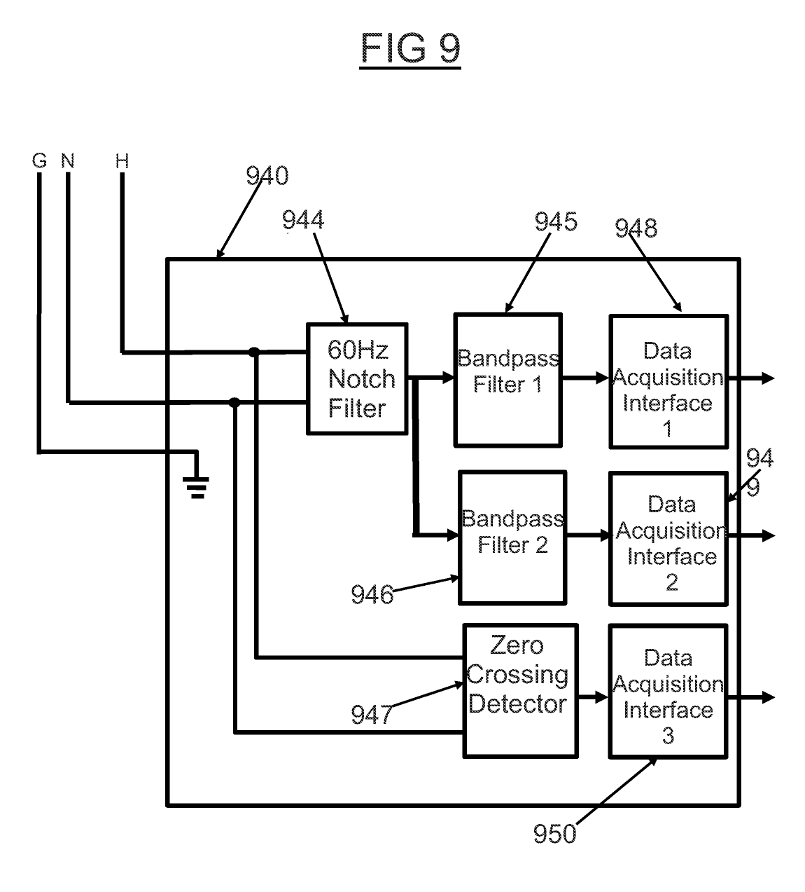

FIG. 9 shows, in more detail, one embodiment of the AC distribution interface and filters 940 comprising a 60 Hz notch filter 944, a bandpass Filter 1 945, a bandpass filter 2 946, Zero Crossing Detector 947, Data acquisition interface 1 948, data acquisition interface 2 949 and data acquisition interface 3 950. The frequency ranges of bandpass filter 1 945 and bandpass filter 2 946 are chosen to best capture the frequencies in the Transient Pulse.

In one embodiment of the AC distribution interface and filters 940, bandpass filter 1 945 and bandpass filter 2 946 may allow frequencies of 50 KHz to 200 KHz to pass through the filter. The 60 Hz notch filter 944, bandpass filter 1 945, Bandpass filter 2 946 and the zero crossing detector 947 may all be standard filter circuits whose schematics are available industry wide and capable of being designed and constructed by one skilled in the art.

In alternative embodiments, additional bandpass, notch, lowpass or highpass filter elements can be added with their own data acquisition interface to the data acquisition circuitry or be added to an existing bandpass filter section.

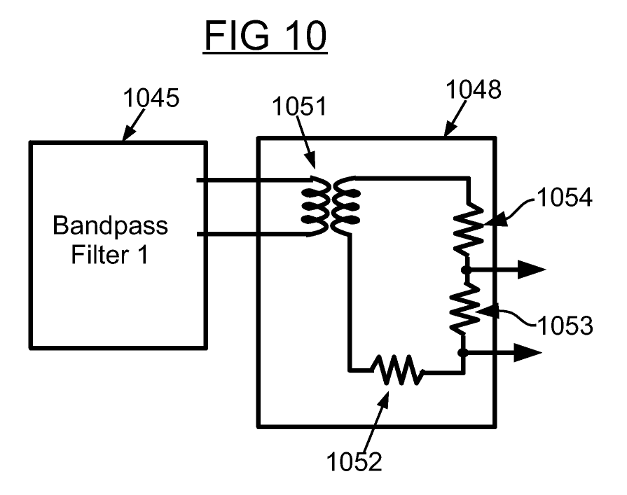

FIG. 10 shows one embodiment of the circuit for data acquisition interface 1 1048. This circuit may also be used for the data acquisition interface 2 or data acquisition interface 3. A preferred embodiment of data acquisition interface 1 may comprise a transformer 1051, resistor R4 1052, resistor R5 1053, and resistor R6 1054. Transformer 1051 may interface data acquisition interface 1 1048 to bandpass filter 1 1045. The transformer may complete a series circuit with resistor R4 1052, resistor R5 1053, and resistor R6 1054.

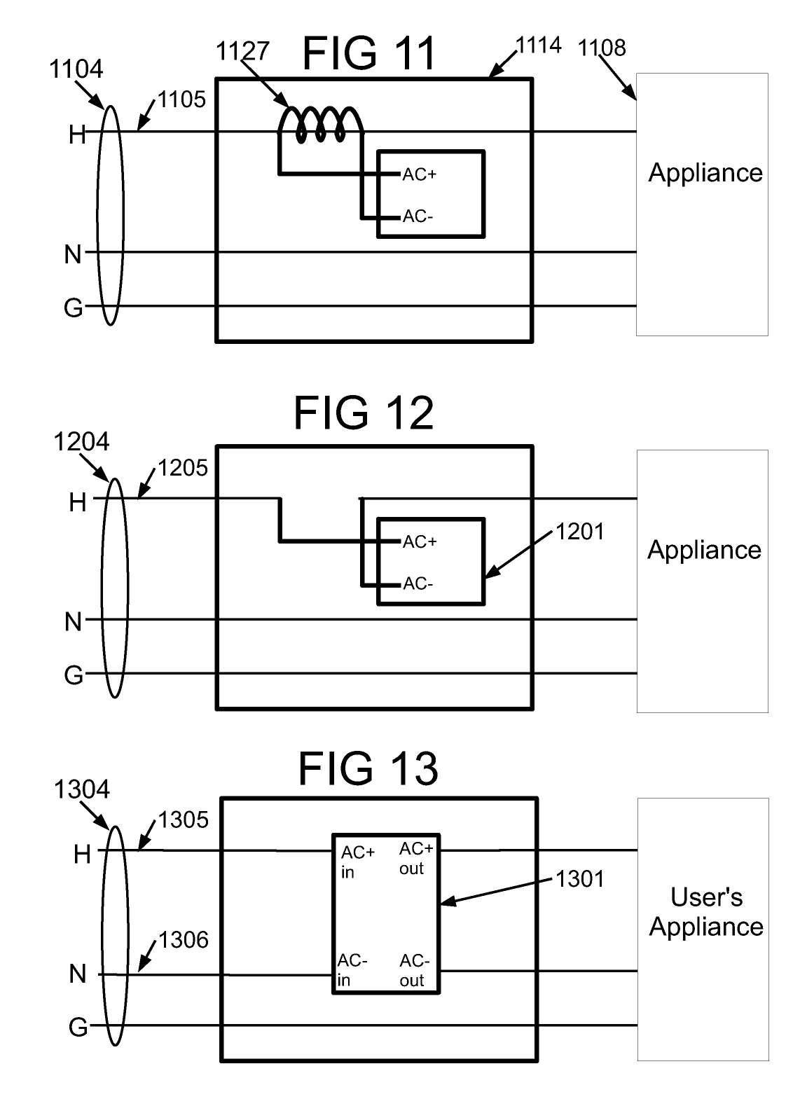

FIG. 11 shows one possible embodiment of the AC interface 1114 of the Sender Unit. Also shown is the AC power distribution wiring 1104, the appliance 1108, and the coil 1127. The coil 1127 is connected in series with the H wire 1105. The terminals of the coil 1127 connect to the remaining circuitry of the sender unit, as shown in FIG. 6.

FIG. 12 shows an alternative embodiment of the AC Interface 1214 of Sender Unit 1201 that couples to the AC power distribution wiring 1204 by being in series with H wire 1205 and components within the alternate embodiment of Sender Unit 1201 connect directly to the H wire 1205 without a coil.

FIG. 13 show yet another alternative embodiment of the AC interface 1314 of Sender Unit 1301 coupled to the AC power distribution wiring 1304. In this embodiment, the sender unit 1301 is in series with both the H wire 1305 and the N wire 1306. Components within the alternate embodiment of Sender Unit 1301 connect directly to the H wire 1305 and the N wire 1306.

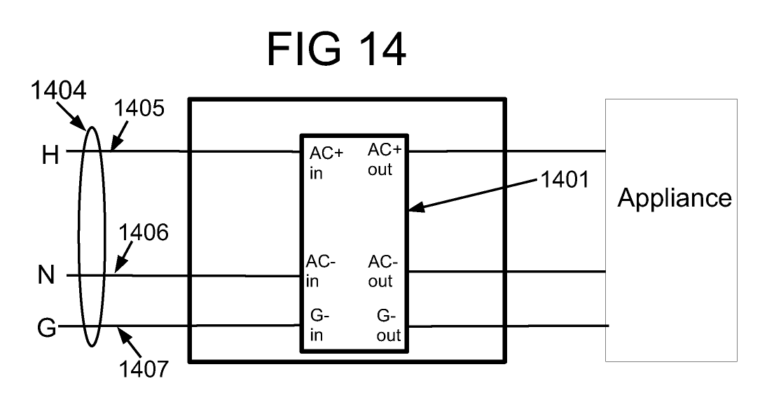

FIG. 14 shows yet another alternative embodiment of the AC interface 1414 of Sender Unit 1401 coupled to the AC power distribution wiring 1404 by being in series with the H wire 1405, the N wire 1406, and the G wire 1407. Components within this embodiment of Sender Unit 1401 may connect directly to the H wire 1405, the N wire 1406 and the G wire 1407.

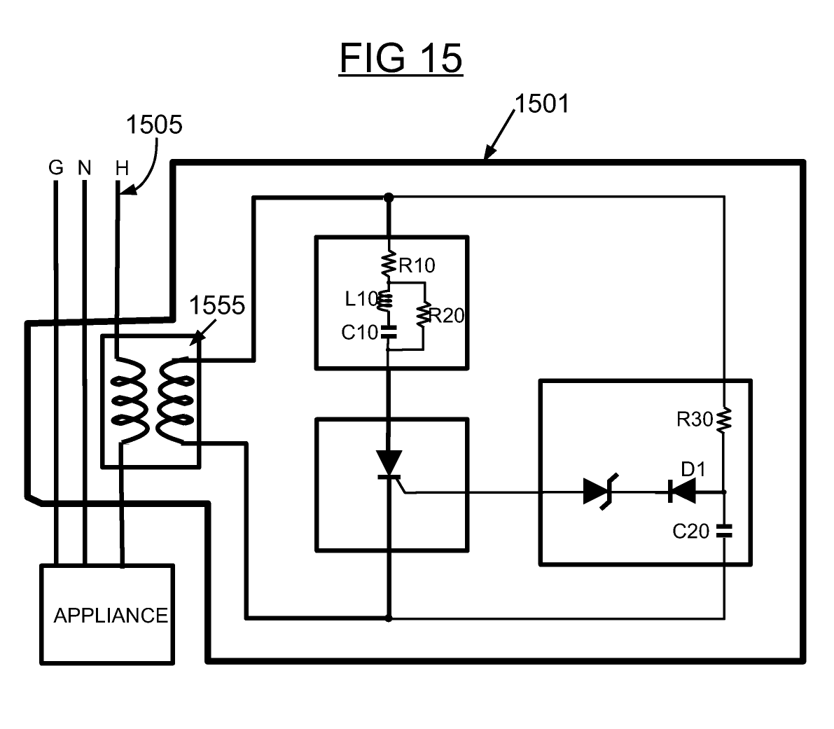

FIG. 15 shows an alternate embodiment of the sender unit 1501 in more detail. This embodiment comprises the AC interface 1514 as shown in FIG. 12. The primary difference between this alternate embodiment Sender Unit 1501 depicted in FIG. 15 and the embodiment depicted in FIG. 6 is the use of an interface transformer 1555 in series with the H wire 1505 instead of a coil 627 around the H wire 605. However, actual component values can also be different may also be different between the two embodiments.

Other possible alternate embodiments of the Sender Unit and Central Detector may utilize different attributes of the Transient Pulse for carrying and detecting information. In one embodiment of the electricity usage monitor system, the information to be carried communicated by the transient pulse may include (1) that the transient pulse is one associated with this Electricity Usage Monitor System, (2) the sender identification tag of the specific Sender Unit of the multiple Sender Units installed in the electricity usage monitor system, (3) the current flowing in the specific appliance associated with the specific Sender Unit. The different attributes of the Transient Pulse that could be used individually or in combination to communicate the information may include (1) the frequencies, duration, relative frequency amplitudes or other of the characteristics of the Transient Pulse, (2) the time position of the transient Pulse relative to the zero crossing point of the AC power distribution wiring waveform, (3) the range of the time position of the Transient Pulse relative to the zero crossing point of the AC power distribution wiring waveform, (4) the frequencies, duration, relative frequency amplitudes or other of the characteristics of the Transient Pulse caused by the switch circuitry turning off, (5) Decay characteristic of the transient pulse, (6) the quarter cycle of the AC power distribution wiring waveform on which the transient pulse occurs, (7) position of the transient pulse relative to a transition from a negative voltage point of the AC power waveform to a positive voltage point.

Different attributes of the transient pulse can be detected by the central detector and carry different information.

When detecting the position of the transient pulse relative to a transition from a negative voltage point of the AC power waveform to a positive voltage point, a minimum amount of voltage change may be required before identifying this transition.

Exemplary, but not limiting, possible embodiments may include (1) detecting the frequencies, duration, relative frequency amplitudes or other of the characteristics of the Transient Pulse and the frequencies, duration, relative frequency amplitudes or other of the characteristics of the Transient Pulse caused by the switch circuitry turning off to determine that the transient pulse is one associated with this Electricity Usage Monitor System, (2) detecting the time position of the transient Pulse relative to the zero crossing point of the AC power distribution wiring waveform to determine the sender identification tag of the specific Sender Unit of the multiple Sender Units installed in the electricity usage monitor system, or (3) detecting the frequencies, duration, relative frequency amplitudes or other of the characteristics of the Transient Pulse caused by the switch circuitry turning off to determine the current flowing in the specific appliance associated with the specific Sender Unit. Each of these may be detected separately by an electricity usage monitor system or each of these may be detected simultaneously on a single transient pulse.

Alternative embodiments of Sender Unit include installing all of the sender unit circuitry within (1) the box of a standard electrical socket, (2) a standard lamp electrical box, (3) the appliance, for example, but not by way of limitation, the outdoor compressor unit of an air conditioning system or the fan and condenser unit of an air conditioning system, (4) a standard electrical socket device during manufacture of those devices (such electrical socket devices could then be sold in wholesale or retail stores for electrical contractors or homeowners to install in electrical AC outlets), (5) an electrical appliance or device, for example but not by way of limitation, lamps, refrigerators, or the like, during manufacture of those appliances or devices, (6) a standard electrical breaker panel (in this embodiment, the Sender Unit may measure the current drawn from a single breaker, multiple breakers, or the total main current coming into the building), (7) the electrical box of the AC outlet (in this embodiment, the circuitry could be preinstalled on the AC outlet before installation or, alternatively, be built into the AC outlet during manufacturing), (8) a light switch used in the AC power distribution wiring (in this embodiment, the circuitry could be preinstalled before installation in the AC power distribution wiring or be built into the switch during manufacturing), or (9) a standard electrical box used in the AC power distribution wiring system (in this embodiment, the circuitry could be preinstalled before installation or be built into the switch during manufacturing).

In an embodiment in which the sender unit circuitry is installed within the outdoor compressor unit of an air condition system and within the fan and condenser unit of an air conditioning system, the Central Detector may be programmed to add the current reading of these two appliances together for reporting the air conditioning systems power or current consumption.

In an alternate embodiment of the sender snit and the software programs of the central detector, component values may be adjusted to work with different AC Power distribution wiring voltages or frequencies such as 210 Vac 50 Hz as found in non USA countries and in local special power distribution systems.

In an alternative embodiment a coupling device may be installed to allow the Transient Pulse to travel more easily from one phase of the AC Power Distribution wiring to another phase. This coupling device may allow higher frequencies to pass from one phase to the other but not allow the frequency of the AC power itself to pass from one phase to another. The coupling device may be wired into the main electrical breaker or may be built into an adapter that plugs into a multi-phase plug. In an exemplary, but not limiting embodiment, a coupling device may be built into an adapter that plugs into a 240Vac 2 phase 30 amp Dryer outlet.

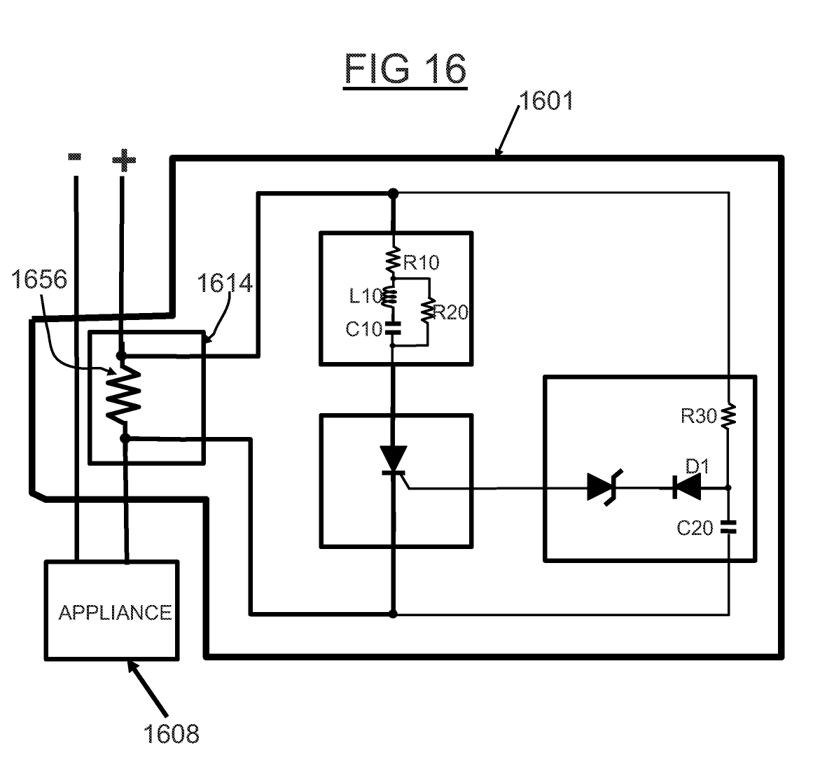

Another alternate embodiment of the Sender Unit may comprise changes to the AC interface and component values to allow the electricity usage monitor system to work with DC power distribution systems. An exemplary, but not limiting, embodiment may comprise modifying the Sender Unit 1601 as depicted in FIG. 16. In such an embodiment, resistor R40 1656 has a very low resistance value so as not to significantly affect the power being delivered to the appliance 1608. The values of the other components are selected such that the rest of the circuit has very high impedance relative to the typical appliance 1608, for example, 1 mega ohm or more.

The Central Detector interface may be modified similarly. For example 60 Hz Notch Filter and the Zero Crossing Detector may have components that are capacitively coupled to the DC power distribution wiring or would be very high impedance to the DC power distribution wiring relative to the impedance of the typical appliance.

The circuitry shown in FIG. 16 may also be used for AC power distribution systems. FIG. 16 is one alternative embodiment of the Sender Unit 1601 utilizing the AC interface 1614 shown in FIG. 12.

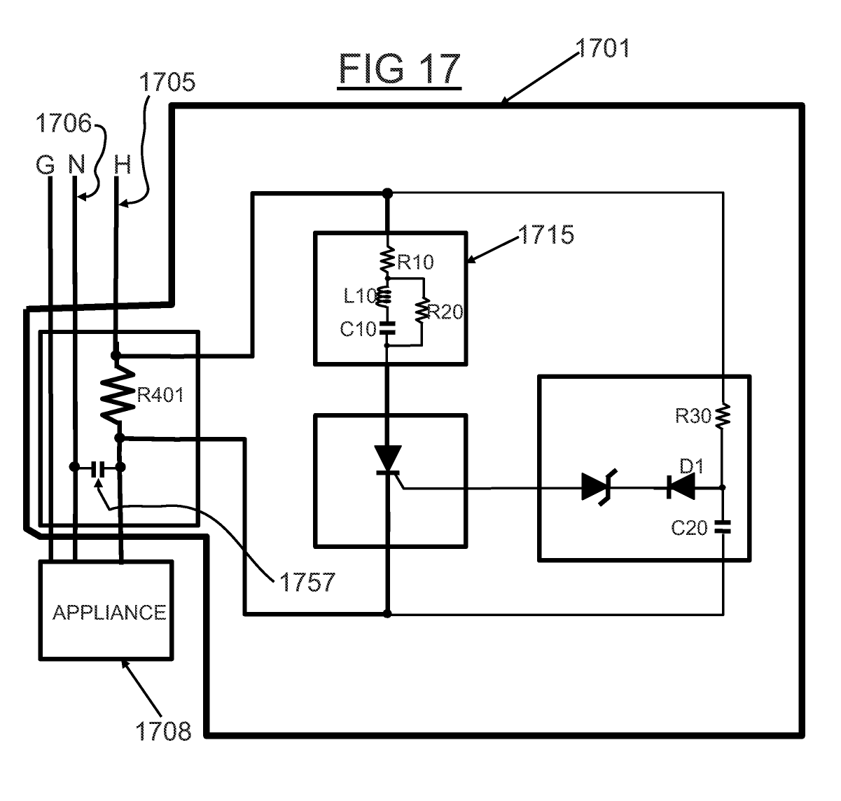

FIG. 17 shows another alternate embodiment of the Sender Unit 1701 which adds a high frequency bypass capacitor 1757. The high frequency bypass capacitor 1757 provides a high impedance to the AC or DC power distribution current to the appliance 1708 but provides a low impedance to the frequencies generated by the transient pulse generator 1715 so that the pulse may pass easily between the H wire 1705 and the N wire 1706. This is in case the appliance 1708 provides high impedance to the frequencies generated by the transient pulse generator and thus would cause a lower level signal for the Transient Pulse. The high frequency bypass capacitor 1757 may also be used in other embodiments described here in for the same purpose.

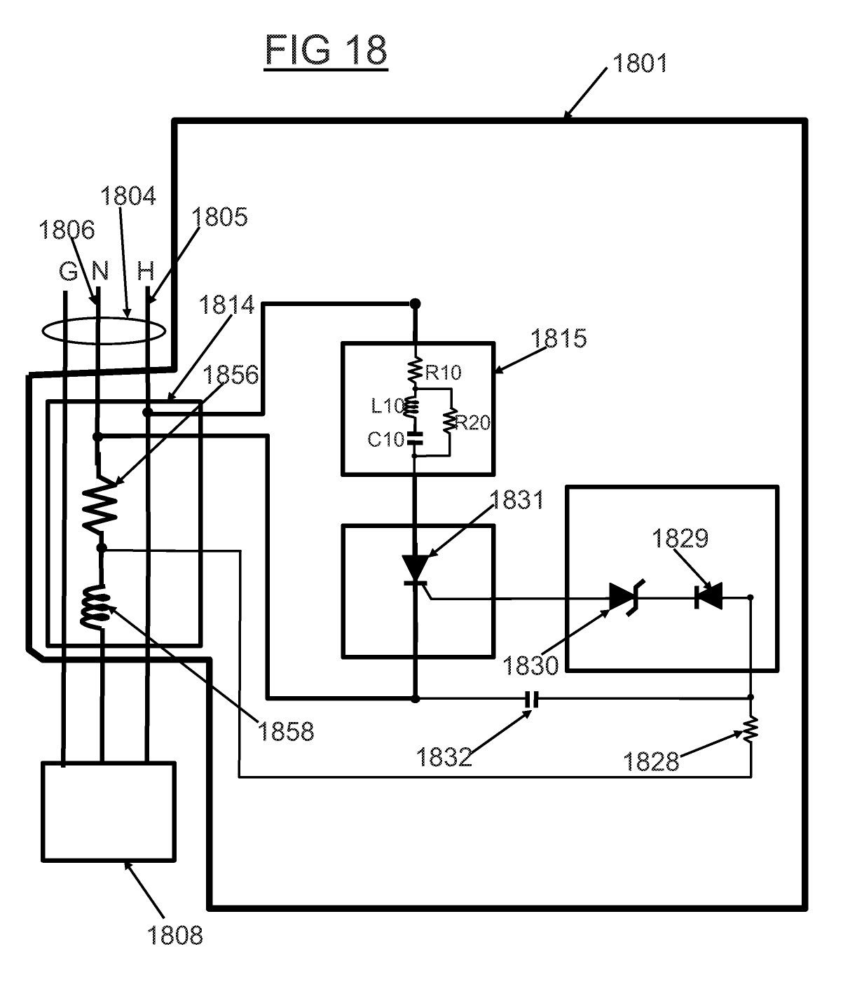

FIG. 18 shows an embodiment of the sender unit 1801 in which a high frequency bypass capacitor may not be needed. This may be because the appliance 1808 may pass the high frequencies being used for the Transient Pulse. Sender Unit 1801 provides an alternative connection to the AC power distribution wiring 1804 specifically in the trigger operation of the SCR 1831. The voltage generated across resistor R40 1856 when current flows to and from the appliance 1808 provides the primary SCR trigger voltage via resistor R3 1828, diode D1 1829, optional zener diode 1830 and capacitor C2 1832. The transient pulse generated by the SCR 1831 and the transient pulse generator 1815 will be applied across the H wire 1805 and N wire 18 and thus can be a more separate voltage than used for triggering. As in all circuit diagrams herein, FIG. 18 does not include the industry standard protection and bias circuitry that may be included in practice.

In more detail, FIG. 18 shows circuitry for generating the Transient Pulse on the first quarter cycle of the AC power distribution wiring waveform. Alternative circuits or alternative component values are used for generating the pulse on second quarter cycle, third quarter cycle, and fourth quarter cycle.

The AC Interface 1814 comprises a resistor R40 1856 and a high frequency blocking inductor 1858 in series with N wire 1806. The high frequency blocking inductor 1858 may not be needed for all applications, such as when the appliance 1808 has a high enough impedance at the high frequencies of the Transient Pulse such that the appliance 1808 will not excessively short out the Transient Pulse.

When current flows to the appliance 1808 a current is caused to flow in resistor R40 1856. The voltage developed across resistor R40 1856 will be applied through resistor R3 1828 then across SCR 1831 cathode and gate, optional zener diode 1830 and diode D1 1829. This voltage will also be applied across capacitor C2 1832 which causes a phase shift which allows SCR 1831 to fire at a different point in time as referenced to the AC power distribution wiring waveform zero crossing point than the AC power distribution wiring waveform would cause without capacitor C2 1832. Varying or elimination of capacitor C2 1832 allows turning on SCR 1831 at different points in time on the AC power distribution wiring waveform for different Sender Units 1801 as well as allowing turn on during the second quarter cycle and forth quarter cycle. Note that this is AC current and in this embodiment shown in FIG. 18 only the positive cycle of the current would cause the current described to flow.

When the voltage across resistor R40 1856 including the phase shift caused by capacitor C2 1832 becomes high enough to cause the voltage at the gate of the SCR 1831 to fire, SCR 1831 will turn on and conduct current in the loop comprising transient pulse generator 1815, SCR 1831, the circuitry on the N wire 1806 and the H wire 1805, including that of the AC power distribution wiring 1804 and remote appliances 1808 connected to it as well as the resistor R40 1856, high frequency blocking inductor 1858, and the appliance 1808. When the current first starts flowing a transient pulse will be generated which last a very short period relative to the AC power distribution wiring waveform cycle period. The specific characteristics of this transient pulse are controlled by the transient pulse generator 1815 comprising an RLC circuit and also by the SCR 1831 switching characteristics. Current continues flowing in this loop until it decreases to near the zero crossing point which causes the SCR 1831 to turn off. A different transient pulse may be generated at the turn off time and this off pulse may be ignored by the Central Detector or it may be used in conjunction with the turn on time transient pulse for validating that these pulses came from one from one of the Sender Units 1801.

Referring to FIG. 7 and FIG. 4 along with FIG. 18, the alternative embodiment of the Sender Unit 1801 will utilize an appliance 1808 high voltage waveform 733 and an 1808 appliance lower voltage waveform 734 to cause the transient pulse to appear at varying locations on the AC power distribution wiring waveform. The location of the transient pulse is based on the voltage developed across resistor 1856 which is relative to the current flowing into the appliance 1808. The voltage developed across resistor 1856 will affect the firing time of SCR 1831.

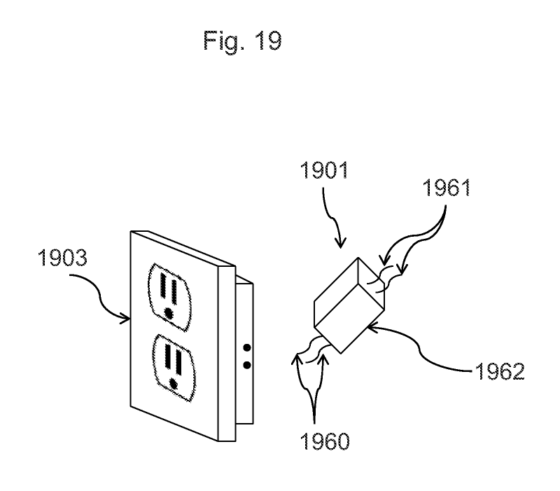

The sender unit may be packaged and connected to an AC power distribution wiring system in a number of ways. In some embodiments, sender units may be packaged in a way allowing them to be used to retrofit existing AC outlets. FIG. 19 depicts an inline embodiment of the sender unit 1901 by which existing AC outlets 1903 may be retrofitted. In this embodiment, the sender unit 1901 may comprise two socket side wires 1960 that may be connected to the existing AC outlet 1903. The sender unit 1901 may also comprise two AC power distribution wiring side wires 1961 that may be connected to the AC power distribution wiring. All of the electronics for the sender unit 1901 may be molded or potted into a compact sender unit housing 1962. In this embodiment, the sender unit 1901 may reside inside the electrical box for the receptacle, switch, or appliance to which the sender unit 1901 is connected. Alternatively, the sender unit 1901 may reside within the appliance itself.

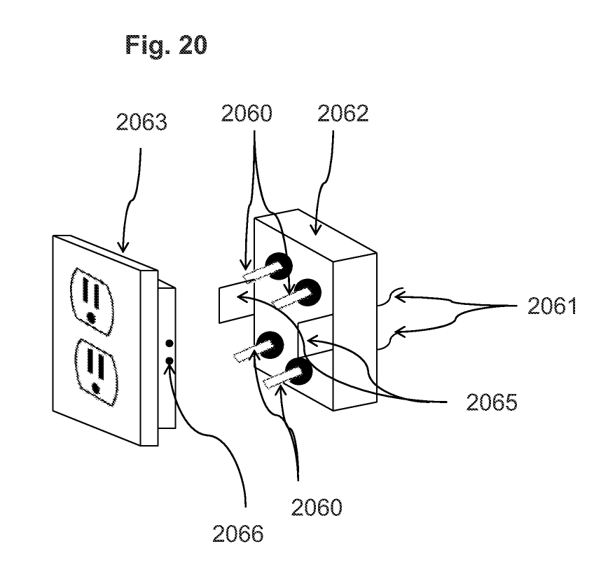

An alternate embodiment for packaging the sender unit to allow it to be used in applications requiring retrofit is shown in FIG. 20. In this snap-on embodiment, the sender unit circuitry may be molded into a sender unit housing 2062 that is pushed into the rear of a commercial electrical receptacle or switch. The sender unit may comprise four socket side wires 2060 protruding from the sender unit housing 2062 and positioned to align with and be inserted into the commercial electrical receptacle or switch 2063 wire holes. The sender unit housing 2062 may comprise a small grommet 2064 secured to the sender unit housing 2062 around each socket side wire 2060. The small grommet 2064 may have some elasticity to allow it to compress slightly when the sender unit housing 2062 is secured to the commercial electrical receptacle or switch 2063. When the socket side wires 2060 of the snap-on embodiment of the sender unit housing 2062 are pushed into the wire holes of the commercial electrical receptacle or switch 2063, the commercial electrical receptacle or switch 2063 may grip the socket side wires 2060 strongly to prevent removal of the socket side wires 2060 and the four small grommets 2064 may be compressed to provide additional force to secure the sender unit housing 2062 and the commercial electrical receptacle or switch 2063 to one another. When the snap-on embodiment of the sender unit housing 2062 is installed on the commercial electrical receptacle or switch 2063, the screws 2066 on the commercial electrical receptacle or switch 2063, which may be used to secure AC wiring, may be removed and discarded. Additionally, the sender unit housing 2062 may comprise tabs 2065 protruding toward the commercial electrical receptacle or switch 2063 that may cover the original AC wiring retention screws of the commercial electrical receptacle or switch 2063 and prevent the installer from using these screw holes. In alternate embodiments, the sender unit housing 2062 may have holes in the tabs that align with the commercial electrical receptacle or switch 2063 AC wiring retention screw holes to allow nylon or other non-conductive screws to be inserted to provide a more mechanical hold of the sender unit housing 2062 to the commercial electrical receptacle or switch 2063 is desired. The sender unit may also comprise two AC power distribution wiring side wires 2061 that may protrude from any side of the sender unit housing 2062. However, in a preferred embodiment, the AC power distribution wiring side wires may protrude from the side of the Sender unit housing 2062 opposing the side of the sender unit housing 2062 from which the socket side wires 2060 protrude. The AC power distribution wiring side wires 2061 may be connected to the AC power distribution wiring. As an example, but not by way of limitation, the AC power distribution wiring side wires 2061 may be connected to the AC power distribution wiring by twist-type wire connectors. In an alternate embodiment, four AC power distribution wiring side wires may protrude from the sender unit housing 2062 and be connected to the AC power distribution wiring.

In an alternate embodiment, the sender unit circuitry may be built into a commercial electrical receptacle or switch, allowing the installer to install the electronic component in the same manner as electronic components without the sender unit circuitry. While such an embodiment may alter the dimensions of the commercial electrical receptacle or switch, installation of the device may be unaffected by the presence of the sender unit circuitry. The sender unit circuitry has a low power consumption and small physical size, which enables it to be built into a commercial electrical receptacle or switch.

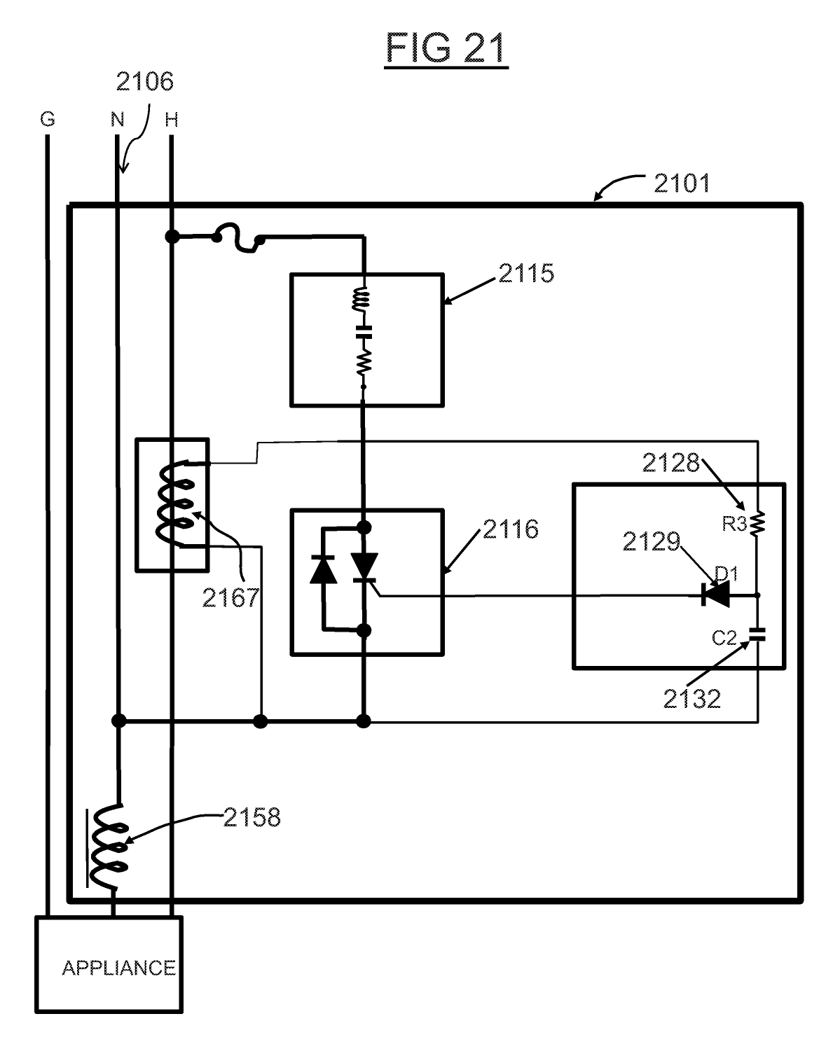

FIG. 21 shows an embodiment of the sender unit 2101 comprising a transient pulse generator 2115, switch circuitry 2116, and current transformer 2167. The current transformer 2167 may detect the current flowing in the circuit. Ln 1 function and ln 3 function may comprise the current transformer 2167. Ln 2 function may comprise capacitor C2 2132. The signals comparator may comprise resistor R3 2128 and diode D1 2129. The high frequency blocking inductor 2158 may be in series with the N wire 2106.

The transient pulse generator 2115 may be comprised of a 10 μH inductor, a 0.1 μF capacitor and a 100Ω resistor in parallel with a 1N4004 diode. Resistor R3 2128 may comprise a 520Ω to 1 kΩ resistor. Diode D1 2129 may comprise a 1N4004 diode. The switch circuitry 2116 may comprise a 1N4004 diode in parallel with an SCR such as an MCR100-8. Capacitor C2 2132 may comprise a 0.01 μF capacitor. These values are provided for exemplary purposes only and not my way of limitation.

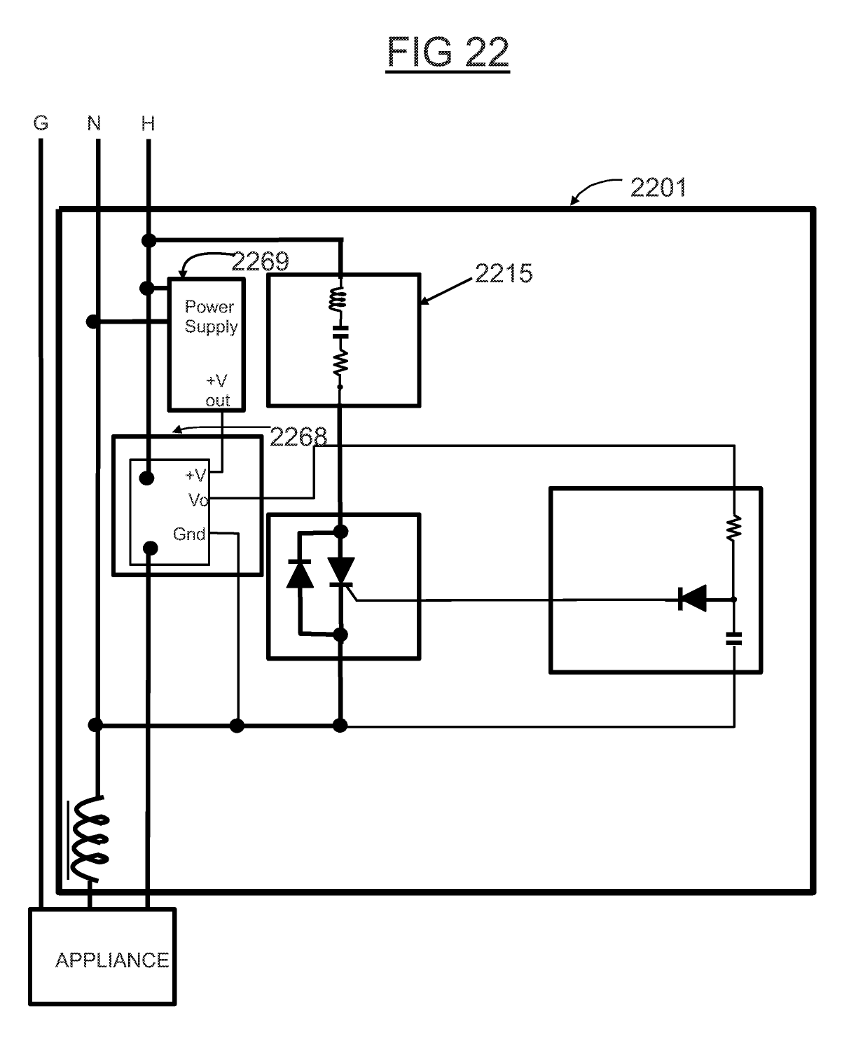

FIG. 22 shows an embodiment of the sender unit 2201 comprising a transient pulse generator 2215 and a hall effect sensor 2268 to detect current flowing in the circuit. A power supply 2269 may be added to the sender unit 2201 to provide power to the hall effect sensor 2268. The hall effect sensor 2268 may be an ACS 713 or like component.

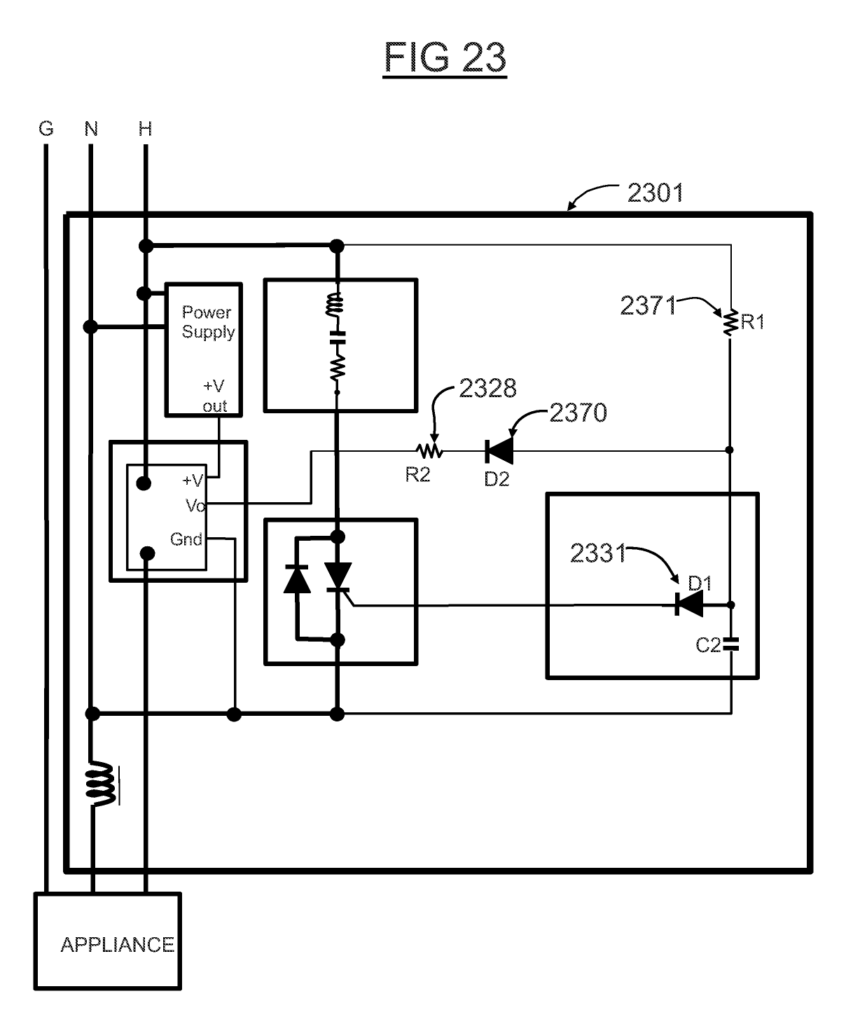

FIG. 23 shows an embodiment of the sender unit 2301. In this embodiment, the signals comparator may comprise diode D1 2331, diode D2 2370, and resistor R2 2328. Ln 3 function may comprise resistor R7 2371.

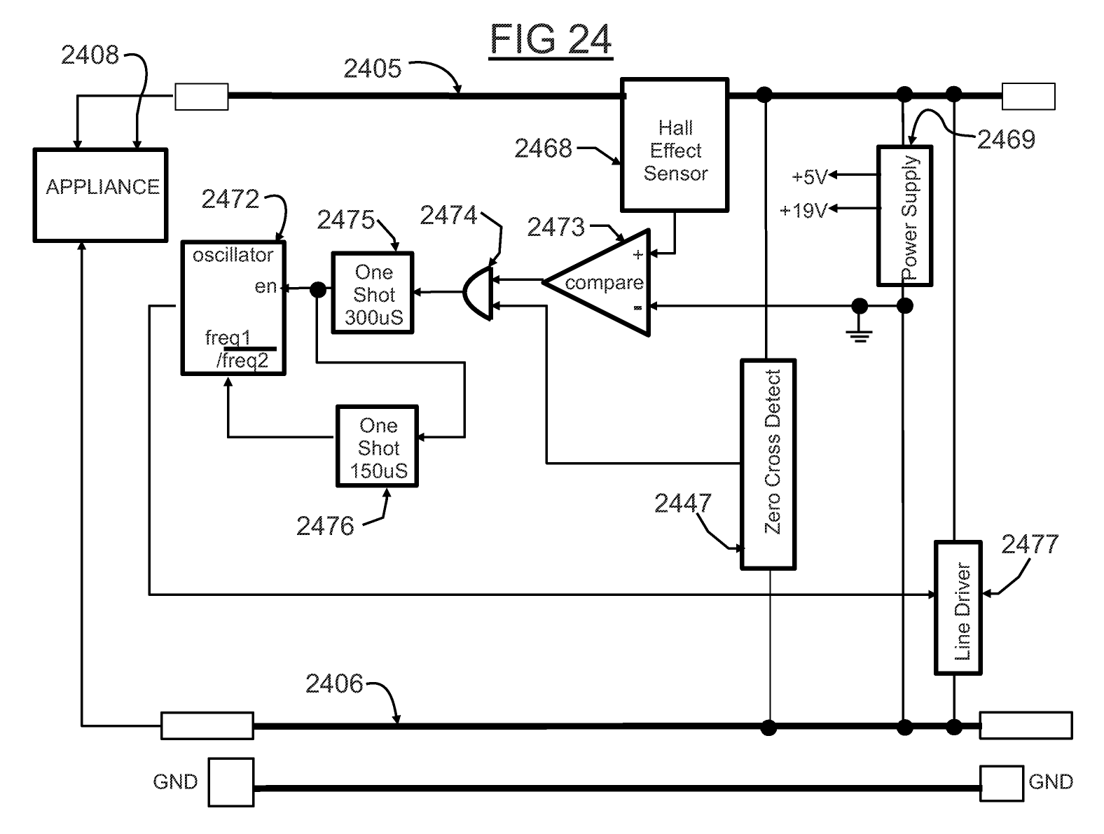

FIG. 24 shows a block diagram of an alternative embodiment of the sender unit 2401. This embodiment may comprise an oscillator 2472, a Hall effect sensor 2468, and a zero crossing detector 2447. The Hall effect sensor 2468 may provide an AC waveform with voltage relative to the current flowing through the H wire 2405 to the appliance 2408. This AC waveform may be input to the compare circuit 2473, which provides a trigger output when the Hall effect sensor 2468 output reaches a predetermined value. This may be at a different time from the AC power distribution wiring waveform zero crossing dependent upon the amount of current flowing in the circuit. The compare circuit 2473 may also include the circuit necessary to provide the ln 2 function, the sender identification tag. The output of the compare circuit 2473 may be input to the AND function 2474 along with the output of the zero crossing detector 2447. The output of the AND function 2474 may trigger a 300 μs one shot circuit 2475, which may output a 300 μs signal to the oscillator 2472 to turn it on. The output of the 300 μs one shot circuit 2475 may also be input to the 150 μs one shot circuit 2476. The 150 μs one shot circuit 2476 may output a 150 μs signal to the frequency selector input of the oscillator 2472. This may cause the oscillator 2472 to output frequency 1 for 150 μs and then change to frequency 2 for an addition 150 μs. The output of the oscillator 2472 may be input to an AC line driver 2477 which may embed the signal onto the AC power distribution wiring waveform. Additionally the circuitry may comprise a high frequency blocking inductor 2458 in series with the N wire 2406 to prevent leakage of the frequency 1 and frequency 2 signals through the appliance 2408 and thus decreases the attenuation of the output of the AC line driver 2477. The power supply 2469 may provide the voltage required by the hall effect sensor 2468, logic circuitry and the AC line driver 2477. The power supply 2469 may be configured to turn on only when power is needed to improve the efficiency of the sender unit 2405.

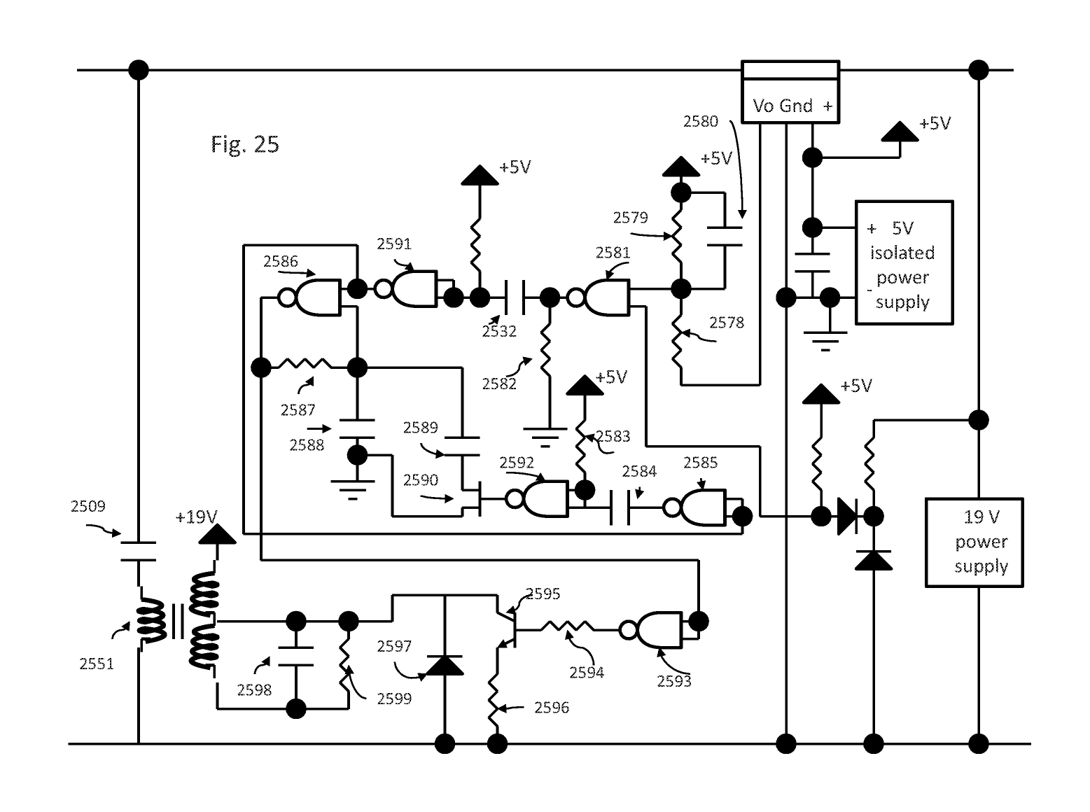

FIG. 25 provides a more detailed depiction of the sender unit block diagram of FIG. 24. The compare circuit may comprise capacitor C2 2532, resistor R8 2578, resistor R9 2579, capacitor C3 2580, gate G1 2581, and resistor R10 2582. The 300 μs one shot circuit may comprise resistor R11 2583, capacitor C4 2584, and gate G2 2585. The oscillator may comprise gate G2 2585, gate G3 2586, resistor R12 2587, capacitor C5 2588, capacitor C6 2589, and FET 2590. The 150 μs one shot circuit may comprise gate G4 2591, capacitor C4 2584, resistor R11 2583, and gate G5 2592. The AC line driver may comprise gate G6 2593, resistor R13 2594, transistor T1 2595, resistor R14 2596, diode D2 2597, capacitor C7 2598, resistor R15 2599, capacitor C8 2509, and transformer 2551.

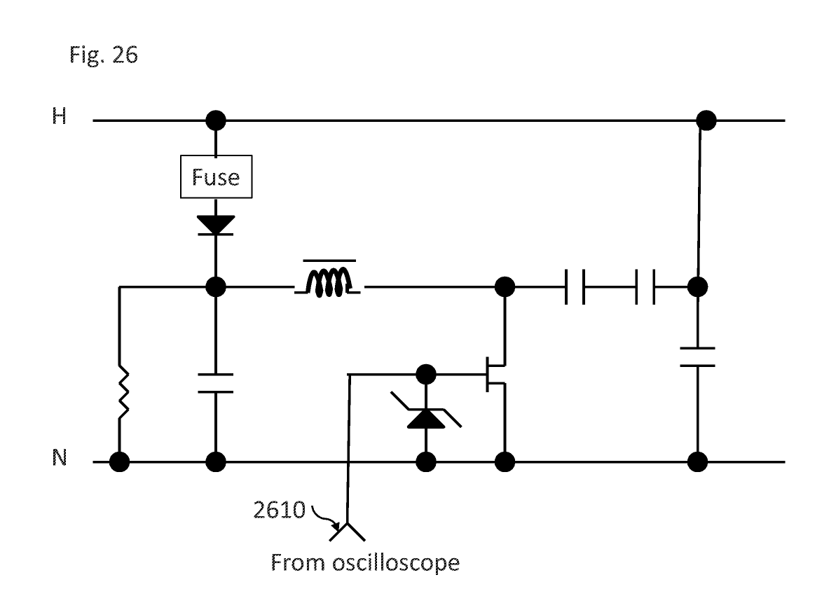

FIG. 26 depicts an alternate embodiment of circuitry used to inject pulses on the AC power distribution wiring waveform. This circuit receives a 5 V to 9 V square wave input from oscillator circuitry at input point 2610. The inductance and capacitance in this circuit smoothes the square wave input to shape it more closely to sine waves and injects the signal on the AC power distribution wiring waveform.

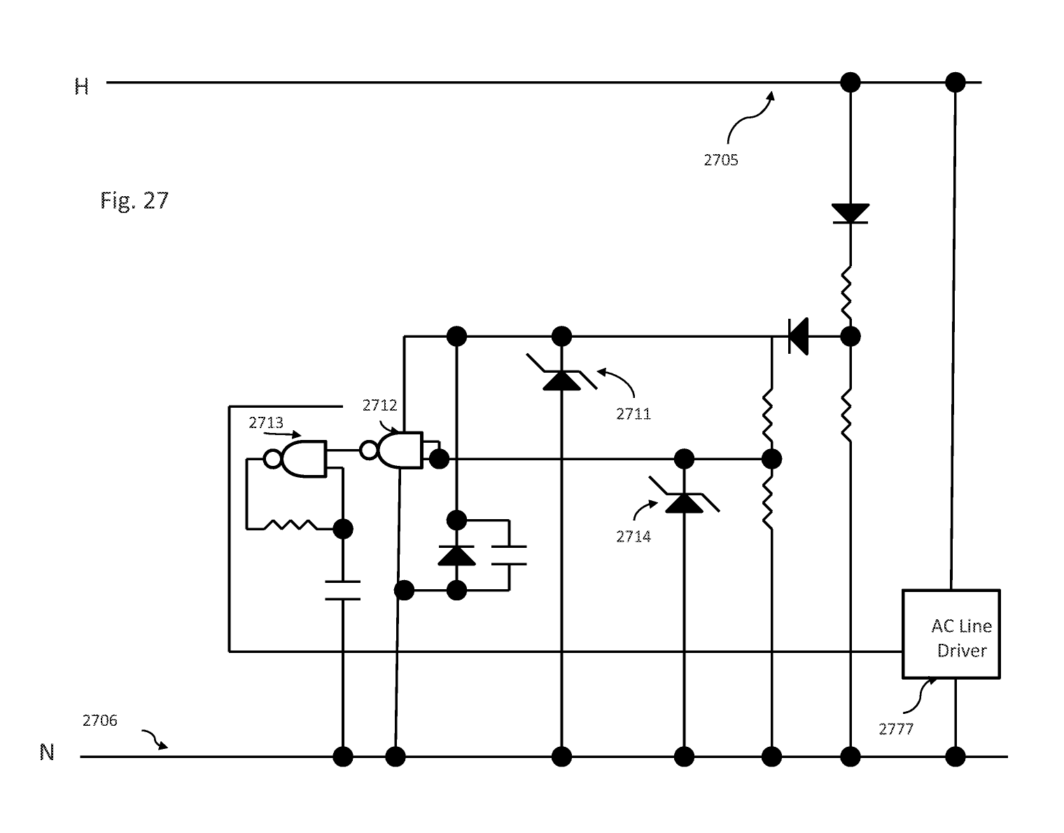

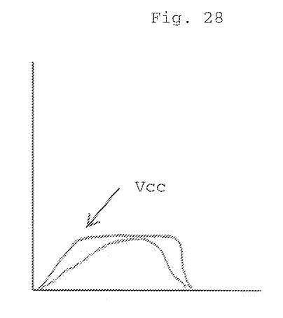

FIG. 27 depicts an alternate embodiment of circuitry used to control the oscillator. When the voltage of the H wire 2705 is sufficiently high relative to the voltage of the N wire 2706, zener diode Z1 2711 turns on and provides voltage to the power pin of gate G7 2712. When gate G7 2712 initially receives a voltage level at its power pin high enough to turn gate G7 2712 on, the voltage levels at the input pins will be logical ‘0’'s so the output of gate G7 2712 will initially be high and cause the output of the oscillator comprising gate G8 2713 to be high. Therefore, a signal will be supplied to the AC line driver 2777. As the voltage on H wire 2705 continues to rise, zener diode Z2 2714 will turn on and clamp the input voltage levels to gate G7 2712. As this voltage level rises, the input to gate G7 2712 will become logic ‘1’'s and cause the output of gate G7 2712 to be low, this will turn off the output of the oscillator. The output of the oscillator will remain off until the voltage on H wire 2705 rises again.

FIG. 28 depicts the waveform output by the circuit in FIG. 27.

Another alternate embodiment of the Sender Unit would include circuit changes for embedding the Transient Pulse on the second quarter cycle, third quarter cycle, and fourth quarter cycle of the AC power distribution wiring waveform. For a transient pulse to appear on the second quarter cycle, the value of capacitor C2 would be changed such that the phase shift of the signal into the gate of the SCR would cause the SCR to fire during the second quarter of the AC power distribution wiring waveform. Standard design techniques for SCR triggering for implementing this phase shift into the gate of the SCR are well known to those skilled in the art.

For a transient pulse to appear on the third quarter cycle, the polarity of SCR, Diode D1, and Zener Diode would be reversed. For a transient pulse to appear on the fourth quarter cycle, the polarity of SCR, Diode D1, and Zener Diode would be reversed and the value of capacitor C2 would be changed such that the phase shift of the signal into the gate of the SCR would cause the SCR to fire during the fourth quarter cycle of the AC power distribution wiring waveform.

Another alternate embodiment of the Sender Unit and the Central Detector software comprises using the next zero crossing point after the transient pulse along with or instead of the previous zero crossing point.

An alternate embodiment of the Central Detector and its detection software comprises ensuring there are a minimum number of detected pulses from a particular Sender Unit before utilizing the detected information.

Note that the transient pulse is a more complex waveforms than simply changing from one current or voltage to another and back again.

Alternate embodiments of the Sender Unit and the Central Detector software can be made to allow better transient pulse detection in the presence of excessive noise and phase shifting on the AC power distribution wiring or other detection problems. The changes for these embodiments may include (1) actual per unit range can be larger or smaller, (2) actual transient pulse can be made longer or shorter in duration, (3) transient pulse frequency components and levels can be different, (4) use of different transient characteristics for different installations of the sender unit, or (5) utilizing the position in time of the wiring transient pulse relative to the peak of the voltage waveform instead or in addition to the position relative to a zero crossing.

For situations where the appliance uses two phase AC power distribution wiring such as 240Vac, split phase, 60 HZ, the electricity usage monitoring system may be modified to add a complete set of the sender unit circuitry shown in FIG. 4 and FIG. 6 with the coil of the AC Interface on the N wire. The Central Detector may recognize transient pulses from these two Sender Circuits and can be programmed to add the currents detected in each together to get the actual current and calculated power being drawn by the appliance.

Similarly, two complete sets of the Sender Unit circuitry may be added and summed at the Central Unit for three phase appliances and power distribution.

In its broadest embodiment, the present invention is a method of getting information from one point on an AC or DC power distribution system to another point on the AC or DC power distribution system. It does this by utilizing a sender unit which embeds a pulse onto the power signal and a central detector which detects the pulse and analyzes the pulse to determine the information carried by the pulse based on the location of the pulse on the power signal. In an AC power distribution system, the location of the pulse is with reference to the zero crossing of the AC waveform. In a DC power distribution system, the location of the pulse may be with respect to a plurality of other pulses.

While the above description contains much specificity, these should not be construed as limitations on the scope of any embodiment, but as exemplifications of the presently preferred embodiments thereof. Many other ramifications and variations are possible within the teachings of the various embodiments.

Thus the scope of the invention should be determined by the appended claims and their legal equivalents, and not by the examples given.

What is claimed is:

1. A system for monitoring electricity usage comprising:
a plurality of sender units having sender identification tags wherein said plurality of sender units are capable of being connected to AC power distribution wiring, wherein said AC power distribution wiring carries AC waveforms, and wherein said plurality of sender units are capable of being in electrical communication with an appliance having a current draw; and
a central detector capable of being connected to said AC power distribution wiring wherein said plurality of sender units are capable of being in electrical communication with said central detector through said AC power distribution wiring, and wherein said plurality of sender units are capable of transmitting a transient pulse on said AC power distribution wiring wherein said transient pulse is embedded at a location on said AC waveform wherein said location is relative to said sender identification tag and wherein said location is further relative to said current draw of said appliance.
